(19) United States
(12) Patent Application Publication
(10) Pub. No.: US 2020/0219941 A1
(43) Pub. Date: Jul. 9, 2020

(54) CAPACITIVE TOUCH PANEL

(71) Applicant: Raydium Semiconductor Corporation, Hsinchu (TW)

(72) Inventors: CHANG-CHING CHIANG, Taichung City (TW); KUN-PEI LEE, Miaoli County (TW)

(21) Appl. No.: 16/728,044

(22) Filed: Dec. 27, 2019

(30) Foreign Application Priority Data
Jan. 8, 2019 (TW) 108100756

(51) Int. Cl. H01L 27/32; H01L 51/52; H01L 25/18; G06F 3/044

(52) U.S. Cl. CPC H01L 27/323; H01L 27/3276; H01L 51/5256; H01L 24/16; H01L 25/18; G06F 3/0443; H01L 27/3288

(57) ABSTRACT

A capacitive touch panel is disclosed. The capacitive touch panel includes a plurality of pixels. A laminated structure of each pixel includes a substrate, a display layer, a thin-film encapsulation layer and a conductive layer from bottom to top. The display layer is disposed above the substrate. The thin-film encapsulation layer is disposed above the display layer with respect to the substrate. The thin-film encapsulation layer includes alternately stacked organic material layer and inorganic material layer. The conductive layer is disposed above the thin-film encapsulation layer or within the thin-film encapsulation layer. The conductive layer is electrically connected to a connection pad disposed above a non-display area of the display layer.

### BACKGROUND OF THE INVENTION

### 1. Field of the Invention

The invention relates to a display; in particular, to a capacitive touch panel.

### 2. Description of the Prior Art

A conventional organic light-emitting diode (OLED) touch panel includes an OLED substrate, a driving circuit layer formed on the OLED substrate and an organic light-emitting layer formed on the driving circuit layer. Since the organic light-emitting material is easily attenuated by water and oxygen, an encapsulation layer having a good water and oxygen blocking ability is necessary to be formed on the OLED panel.

As shown in FIG. 1, the encapsulation layer 14 can be a glass substrate, and the encapsulation process can use a laser emitter 16 to emit a laser light to cure a frame adhesive material 18 in a frame region to seal the OLED layer 12. Since the glass material has a good barrier effect, the encapsulation layer 14 using the glass material can effectively isolate the water and oxygen from the environment. However, due to the poor flexibility of glass, it is difficult to apply the glass-packaged OLED panel to a flexible or curved display device. In addition, the thinning of glass also has its process limitations. Under the current trend of electronic devices pursuing lightness and thinness, the glass encapsulation also makes it difficult to further reduce the thickness of modules.

In order to solve the above-mentioned problems, the encapsulation layer on the OLED panel can be formed by a thin-film encapsulation technology. As shown in FIG. 2, a thin-film encapsulation layer 24 is formed by stacking at least one organic material layer 24A and inorganic material layer 24B on each other. The thickness of each of the organic material layer 24A and inorganic material layer 24B in the thin-film encapsulation layer 24 is only micrometer (um) level and has a good water and oxygen blocking ability. Since the thickness of the thin-film encapsulation layer 24 is much smaller than that of the glass encapsulation layer and has flexibility, the OLED panel using the thin-film encapsulation layer 24 is easy to apply to the flexible or curved display, and its module thickness can also be effectively reduced.

In order to form an OLED display with a touch function, the touch sensor can be attached to the OLED display in a plug-in way. The plug-in technology can be known technologies such as GFF/G2/G1F.

As shown in FIG. 3 and FIG. 4, a touch flexible circuit board TFPC is provided on the plug-in touch panel to connect a touch sensing electrode 34 and a touch sensing chip TIC, and the touch sensing information can be outputted to the system processor (not shown) through the touch sensing chip TIC. In addition, the OLED substrate can be provided with a driving chip DIC and a driving flexible circuit board DFPC which are bonded by the COG technology to input a display driving signal from a system processor (not shown) to the driving chip DIC to display the screen.

As shown in FIG. 5 and FIG. 6, in the OLED touch panel 5, the touch sensing layer 53 can be formed on the encapsulation layer 52 by an on-cell method. In addition, the touch sensing layer 53 can be connected to the driving flexible circuit board DFPC through the touch flexible circuit board TFPC, and the touch signal is connected to the touch and driving integrated chip TDDI, so that the touch sensing chip TIC can be omitted to reduce costs.

However, in the above-mentioned OLED touch panel, the touch sensing layer still needs to be connected to the touch sensing chip TIC or the driving flexible circuit board DFPC through an additional touch flexible circuit board TFPC. In addition, two separate flexible circuit board bonding processes are required, resulting in the difficulty of further reducing the production cost of the OLED touch panel, which needs to be improved.

### SUMMARY OF THE INVENTION

Therefore, the invention provides a capacitive touch panel to solve the problems occurred in the prior arts.

An embodiment of the invention is a capacitive touch panel. In this embodiment, the capacitive touch panel includes a plurality of pixels. A laminated structure of each pixel includes a substrate, a display layer, a thin-film encapsulation layer and a conductive layer from bottom to top. The display layer is disposed above the substrate. The thin-film encapsulation layer is disposed above the display layer with respect to the substrate. The thin-film encapsulation layer includes alternately stacked organic material layer and inorganic material layer. The conductive layer is disposed above the thin-film encapsulation layer or within the thin-film encapsulation layer. The conductive layer is electrically connected to a connection pad disposed above a non-display area of the display layer.

In an embodiment, the thin-film encapsulation layer is formed by alternately stacking at least one organic material layer and at least one inorganic material layer using a thin-film encapsulation technology.

In an embodiment, the display layer includes a display area and the non-display area.

In an embodiment, the conductive layer includes a touch sensing electrode suitable for mutual-capacitance touch sensing technology or self-capacitance touch sensing technology.

In an embodiment, the conductive layer further includes a trace coupled to the touch sensing electrode, and the touch sensing electrode is electrically connected to the connection pad through the trace.

In an embodiment, the display layer includes an organic light-emitting diode (OLED) multilayer structure.

In an embodiment, the connection pad is electrically connected to a driving circuit, which is a touch driving circuit disposed on a flexible circuit board or a touch and display driving integrated circuit.

In an embodiment, the flexible circuit board includes a first area corresponding to the substrate and a second area corresponding to the thin-film encapsulation layer, and the first area and the second area can be separated from each other to form a separating state.

In an embodiment, another connection pad is disposed on the flexible circuit board or the touch and display driving integrated circuit, and the connection pad and the another connection pad are electrically connected to each other through conductive particles.

In an embodiment, still another connection pad is disposed on the substrate, and the still another connection pad and the another connection pad are also electrically connected to each other through the conductive particles.

In an embodiment, there is a height difference between the connection pad disposed on the thin-film encapsulation layer and the still another connection pad disposed on the substrate.

In an embodiment, the height difference is equal to a thickness of the thin-film encapsulation layer.

In an embodiment, a height of the still another connection pad can be reduced by an OLED process, so that the height difference is smaller than a thickness of the thin-film encapsulation layer.

In an embodiment, a plurality of another connection pads disposed on the flexible circuit board or the touch and display driving integrated circuit include a first connection pad corresponding to the substrate and a second connection pad corresponding to the thin-film encapsulation layer; the first connection pad has a first height and the second connection pad has a second height, and a difference between the first height and the second height is equal to the height difference.

In an embodiment, the thin-film encapsulation layer includes an encapsulation extension area, and the encapsulation extension area is disposed above the non-display area.

In an embodiment, the encapsulation extension area forms a gradient descent structure in a height direction, and the conductive layer is electrically connected to the connection pad through the gradient descent structure.

In an embodiment, the connection pad is disposed on any one organic material layer and any one inorganic material layer of the thin-film encapsulation layer.

In an embodiment, the connection pad is disposed on the non-display area of the display layer.

In an embodiment, the thin-film encapsulation layer includes a first partial encapsulation layer and a second partial encapsulation layer; the conductive layer is formed above the first partial encapsulation layer and the second partial encapsulation layer is formed above the conductive layer; the connection pad electrically connected to the conductive layer is disposed above the first partial encapsulation layer and the second partial encapsulation layer is not formed above the connection pad.

In an embodiment, the capacitive touch panel further includes another conductive layer. The another conductive layer is insulated from the conductive layer. The thin-film encapsulation layer includes a first partial encapsulation layer, a second partial encapsulation layer and a third partial encapsulation layer; the conductive layer is formed above the first partial encapsulation layer and the second partial encapsulation layer is formed above the conductive layer; the another conductive layer is formed above the second partial encapsulation layer and the third partial encapsulation layer is formed above the another conductive layer; the connection pad electrically connected to the conductive layer is disposed on the first partial encapsulation layer and the connection pad electrically connected to the another conductive layer is disposed on the second partial encapsulation layer; the second partial encapsulation layer and the third partial encapsulation layer are not formed above the connection pad.

Compared to the prior art, the invention provides an innovative laminated structure and a trace layout method of a capacitive touch panel to fabricate the touch sensing electrode on or within a thin-film encapsulation layer of an OLED panel, and the touch sensing chip or a flexible circuit board using a chip-on-film (COF) package connects the touch connection pads on the encapsulation layer and the display connection pads on the substrate at the same time, so that the traces of the touch sensing electrodes can be directly connected to a flexible circuit board using the COF package or a touch and drive integrated chip (TDDI), so that the use of flexible circuit boards can be reduced to effectively reduce the manufacturing cost of capacitive touch panel and improve the manufacturing yield.

The advantage and spirit of the invention may be understood by the following detailed descriptions together with the appended drawings.

### BRIEF DESCRIPTION OF THE APPENDED DRAWINGS

FIG. 1 is a schematic diagram illustrating a laminated structure of a capacitive touch panel in an embodiment of the invention.

FIG. 2 is a schematic diagram showing that a conductive layer is disposed on a thin-film encapsulation layer.

FIG. 3 is a schematic diagram showing that a conductive layer is disposed in a thin-film encapsulation layer.

FIG. 4 is a schematic diagram showing that two conductive layers formed in a thin-film encapsulation layer and insulated from each other.

FIG. 5 is a schematic diagram showing that a conductive layer is formed earlier than a conductive filling layer filled in a via.

FIG. 6 is a schematic diagram showing that a conductive layer is formed later than a conductive filling layer filled in a via.

FIG. 7 is a top view of a capacitive touch panel without bonding a flexible circuit board in an embodiment.

FIG. 8 is a schematic cross-sectional view within a dashed box in FIG. 7.

FIG. 9 is a schematic diagram showing that after an OLED and a driving circuit layer are formed, a thin-film encapsulation layer is formed on them.

FIG. 10 is a schematic diagram showing that a touch sensing layer is formed on a thin-film encapsulation layer.

FIG. 11 and FIG. 12 are a top view and a schematic diagram showing that a flexible circuit board using a thin-film flip-chip encapsulation process is bonded to a substrate through a flexible circuit board connection pad.

FIG. 13 and FIG. 14 are schematic diagrams showing that the connection between the flexible circuit board and the substrate and the encapsulation layer of the panel can be connected by conductive particles.

FIG. 15 is a schematic diagram showing that if the bonding process of the conductive particles is performed only once, the down pressure on the conductive particles on the substrate is insufficient.

FIG. 16 is a schematic diagram showing that if the bonding process of the conductive particles is performed only once, the down pressure on the conductive particles on the encapsulation layer is excessive.

FIG. 17 and FIG. 18 are schematic diagrams showing that the bonding process between the display connection pad and the flexible circuit board connection pad by applying a pressing force, and then the pressure is provided to perform the bonding process between the touch connection pad and the flexible circuit board connection pad.

FIG. 19 to FIG. 22 are schematic diagrams showing that when the bonding process is performed in several stages, the region corresponding to the substrate and the region corresponding to the encapsulation layer on the flexible circuit board can form a state of being separated from each other.

FIG. 23 is a schematic diagram showing that a driving chip and a touch sensing chip can be integrated into a touch and driving integrated chip, and can be bonded to a flexible circuit board by a thin-film flip-chip encapsulation process.

FIG. 24 is a schematic diagram showing that an encapsulation extension area formed in a non-display area of the panel can also form a gradient descent structure in a height direction.

FIG. 25 is a schematic diagram showing that in the gradient descent structure, the extension distances of the inorganic material layer and the organic material layer stacked alternately in the encapsulation layer are different, so that the encapsulation layer shrinks from the bottom to the display area in order.

FIG. 26 and FIG. 27 are schematic diagrams showing that the step difference between the touch connection pad and the substrate on the encapsulation layer is significantly reduced.

FIG. 28 is a schematic diagram showing that the touch connection pad is disposed on the substrate and the gradient descent structure of the thin-film encapsulation layer is extended to the substrate to eliminate the height difference between the touch connection pad and the display connection pad.

FIG. 29 is a schematic diagram showing that the touch connection pad is disposed on the non-display area and the gradient descent structure of the encapsulation layer is extended to the non-display area, so that the touch electrode traces formed above the encapsulation layer can be connected to the touch connection pad through the gradient descent structure.

FIG. 30 is a schematic diagram showing that the first partial encapsulation layer, the touch sensing layer and the second partial encapsulation layer are sequentially formed from bottom to top.

FIG. 31 is a schematic diagram showing that the touch connection pad is disposed on the non-display area and the second partial encapsulation layer formed on the touch sensing layer is not formed above the touch connection pad.

FIG. 32 is a schematic diagram showing that touch sensing electrodes and their traces are formed on different encapsulation layers respectively.

FIG. 33 is a schematic diagram showing that the touch connection pads coupled to different touch sensing layers are disposed on different encapsulation layers respectively.

FIG. 34 is a schematic diagram showing that the display connection pads disposed on the substrate are stepped up by the OLED manufacturing process to reduce the step difference between the display connection pads and the touch connection pads.

FIG. 35 and FIG. 36 are schematic diagrams showing that the height difference between the flexible circuit board connection pads disposed on the flexible circuit board with respect to the substrate and the flexible circuit board connection pads with respect to the encapsulation layer is equal to the height difference between the display connection pads disposed on the substrate and the touch connection pads disposed on the encapsulation layer.

FIG. 37 is a schematic diagram showing that the touch and drive integrated chip is directly bonded to the substrate and then connected to the processing system through the flexible circuit board.

FIG. 38 and FIG. 39 are schematic diagrams showing that the height difference between the connection pads disposed on the touch and drive integrated chip with respect to the substrate and the connection pads disposed with respect to the encapsulation layer is equal to the height difference between the display connection pads disposed on the substrate and the touch connection pads disposed on the encapsulation layer.

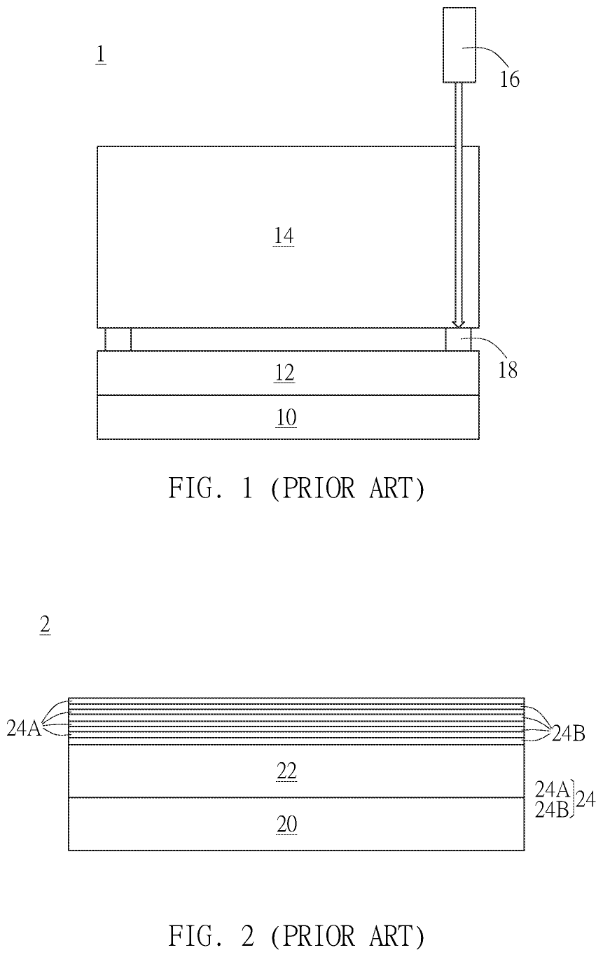

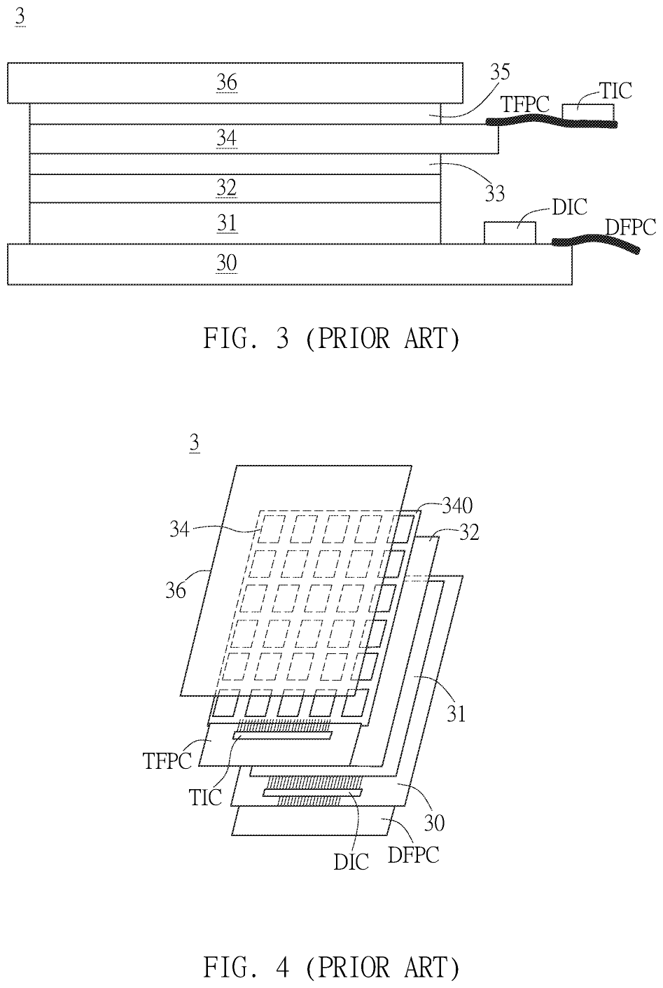

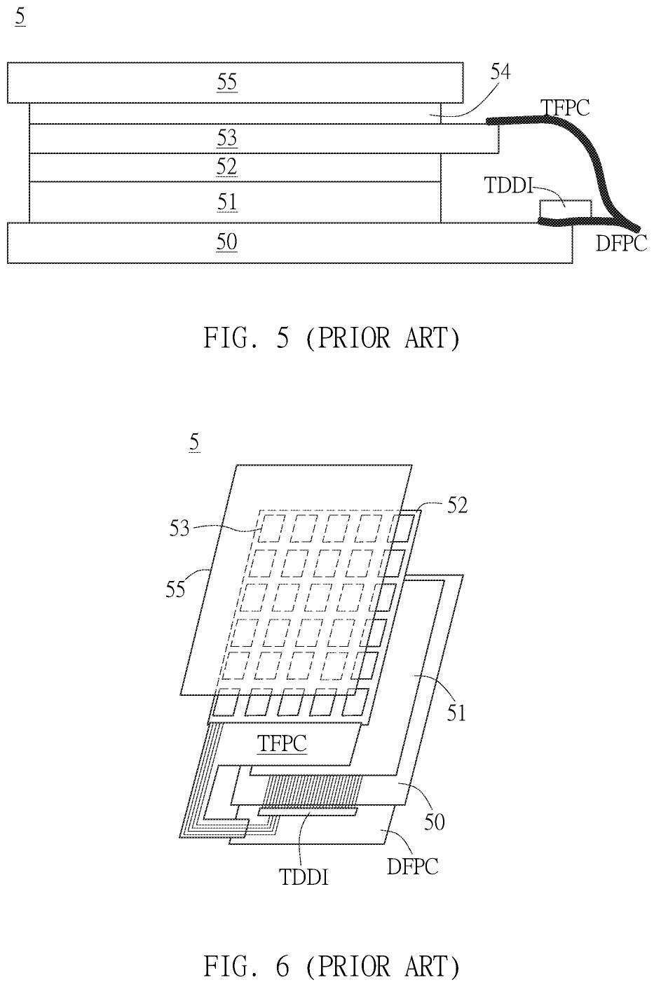

### DETAILED DESCRIPTION OF THE INVENTION

A preferred embodiment of the invention is a capacitive touch panel. In practical applications, the capacitive touch panel can be applied to any self-luminous display (such as an OLED display, but not limited to this) having an on-cell laminated structure and using a thin-film encapsulation technology, and it can be applied to the mutual capacitance touch sensing technology and the self-capacitance touch sensing technology. The touch sensing layer of the capacitive touch panel is composed of a conductive material, and it can be disposed on or within the thin-film encapsulation layer. The thin-film encapsulation layer is formed by alternately stacking at least one organic material layer and at least one inorganic material layer by the thin-film encapsulation technology.

In this embodiment, the capacitive touch panel includes a plurality of pixels. The laminated structure of each pixel includes a substrate, a display layer, a thin-film encapsulation layer and a conductive layer from bottom to top. The display layer is disposed above the substrate. The thin-film encapsulation layer is disposed above the display layer with respect to the substrate. The thin-film encapsulation layer includes at least one organic material layer and at least one inorganic material layer stacked alternately. The conductive layer is disposed above the display layer. The conductive layer is electrically connected to the contacts on the display layer through the vias formed in the thin-film encapsulation layer.

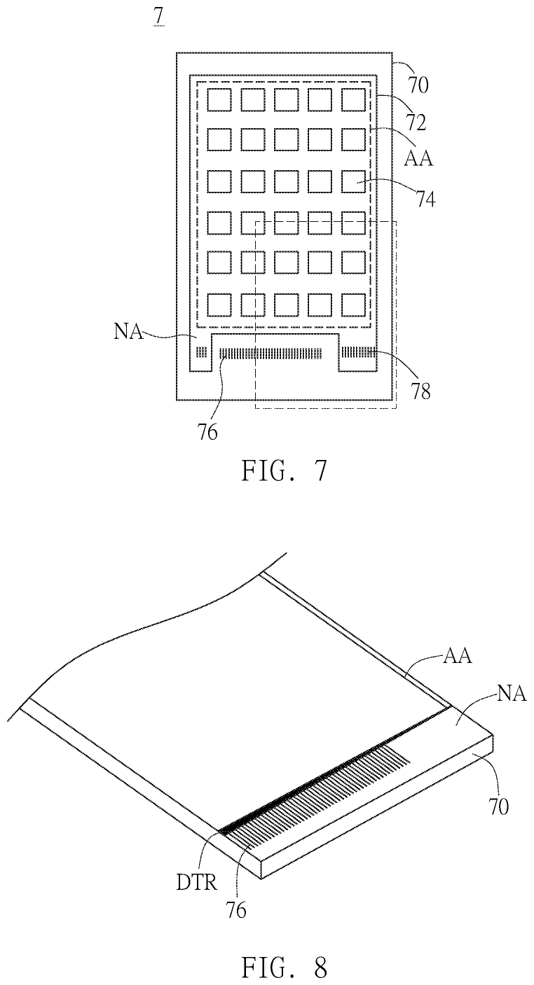

Please refer to FIG. 7. FIG. 7 is a top view of a capacitive touch panel without bonding a flexible circuit board in this embodiment. As shown in FIG. 7, the capacitive touch panel 7 includes a substrate 70, an encapsulation layer 72, a self-capacitance touch sensing electrode 74, a display connection pad 76 and a touch connection pad 78. The capacitive touch panel 7 has a display area AA and a non-display area NA.

It should be noted that it is only an example that the capacitive touch panel 7 includes (5*6) square self-capacitance touch sensing electrodes 74, and not limited to this. In fact, the number of touch sensing electrodes can be more or less, and they can also be mutual capacitance touch sensing electrodes.

Please refer to FIG. 8. FIG. 8 is a schematic cross-sectional view within a dashed box in FIG. 7.

At first, an OLED driving circuit layer is formed on the substrate 70. The processes can be conventional panel processes such as a-Si, LTPS, IGZO, or OLED on Silicon, which are not described herein again. A light-emitting area of the OLED is formed in the display area AA. A display connection pad 76 connected to the driving chip is formed in the non-display area NA of the capacitive touch panel 7.

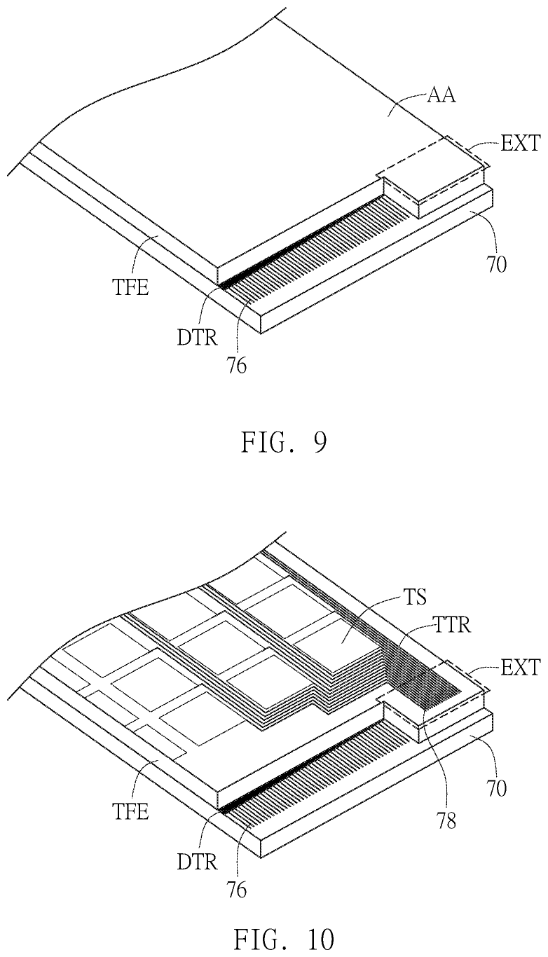

After forming the OLED and its driving circuit layer, an encapsulation layer is formed thereon. As shown in FIG. 9, the encapsulation layer can be a thin-film encapsulation layer TFE having a thickness of about 5 μm or less, and the thin-film encapsulation layer TFE has an encapsulation extension area EXT extending to the non-display area NA of the capacitive touch panel 7. In fact, the thin-film encapsulation layer TFE is formed by alternately stacking at least one organic material layer and at least one inorganic material layer using a thin-film encapsulation technology.

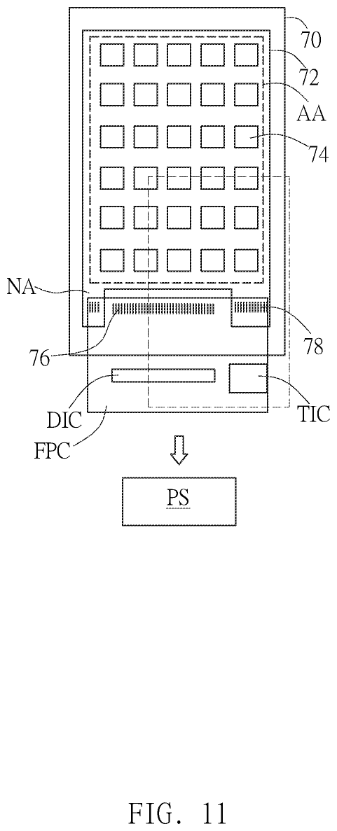

Next, the touch sensing layer can be formed on the thin-film encapsulation layer TFE. The touch sensing layer in FIG. 10 can be a node self-capacitance structure of a single-layer electrode, but not limited to this. In fact, the touch sensing electrodes TS can also be formed by conventional touch panel technologies such as mutual capacitance and one-dimensional self-capacitance. A touch connection pad 78 connecting the touch sensing electrode TS and the touch sensing chip is formed in the encapsulation extension area EXT.

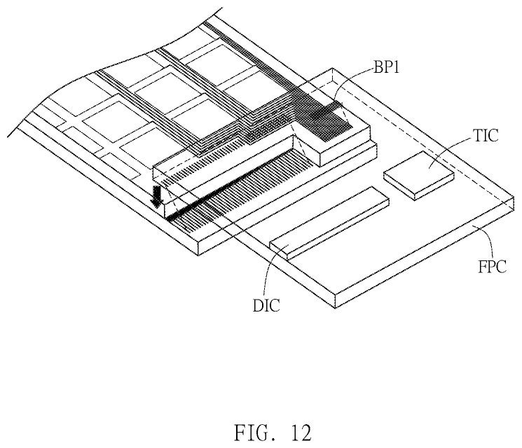

Next, a driving chip DIC and a touch sensing chip TIC are disposed on a flexible circuit board FPC provided with a chip-on-film (COF) process and the flexible circuit board FPC is bonded to the substrate 70 through the flexible circuit board connection pad BP1, and its top view and schematic diagram are shown in FIG. 11 and FIG. 12.

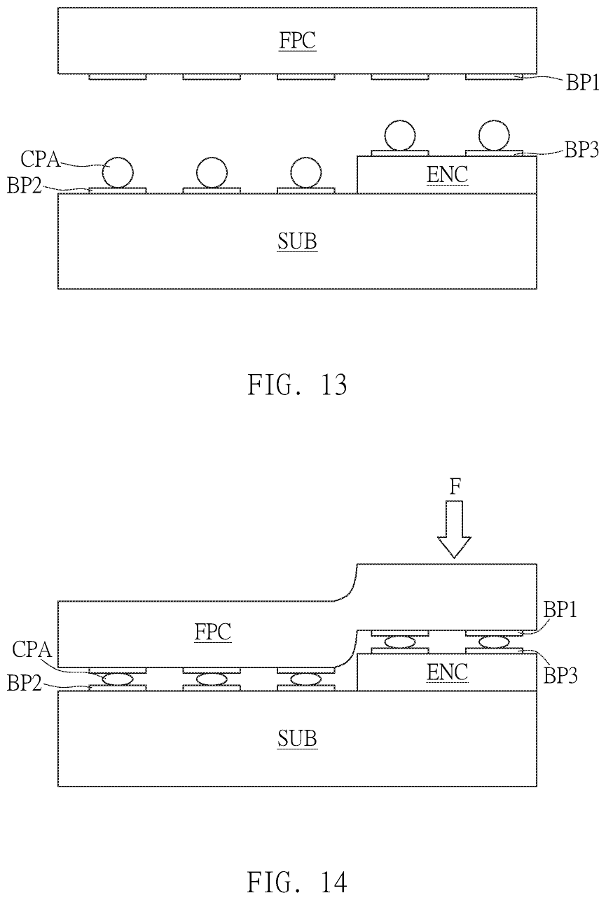

The flexible circuit board FPC and the substrate SUB and the encapsulation layer ENC of the panel can be connected by using the conductive particles CPA, such as the anisotropic conductive film (ACF), as shown in FIG. 13 and FIG. 14.

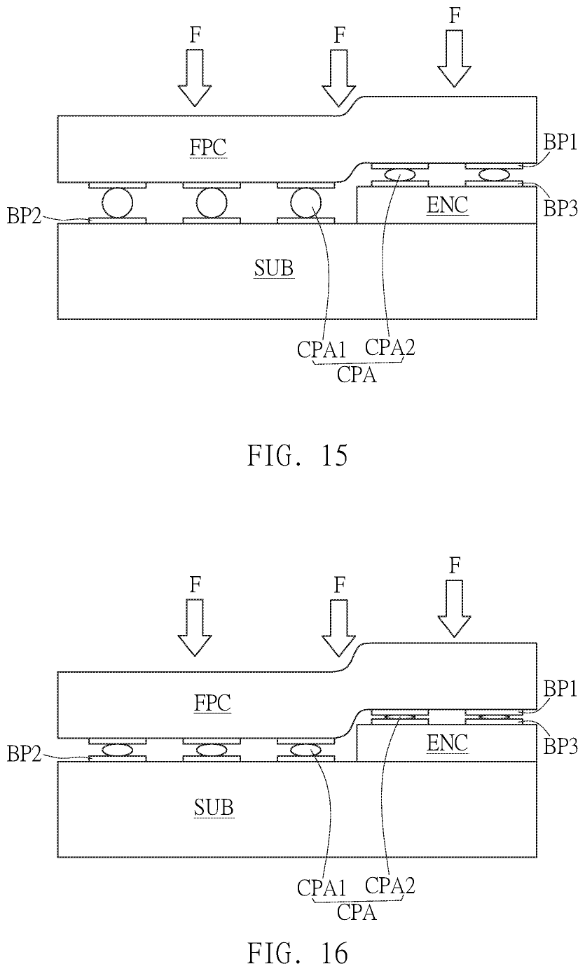

Since the distance between the touch connection pad BP3 on the encapsulation layer ENC and the display connection pad BP2 on the substrate SUB is approximately equal to the thickness of the encapsulation layer ENC (approximately 5 um), if the bonding process of conductive particles CPA is performed only once, although the manufacturing process can be simplified, it may cause the downforce F concentrated on the encapsulation layer ENC due to the height difference between the encapsulation layer ENC and the substrate SUB, so that the down pressure acted on the conductive particles CPA1 located on the substrate SUB is insufficient, resulting in poor conductivity between the substrate SUB and the flexible circuit board FPC, as shown in FIG. 15. On the other hand, when the down pressure applied to the conductive particles CPA1 located on the substrate SUB is sufficient, the conductive particles CPA2 located on the encapsulation layer ENC are subjected to excessive down pressure, which causes the conductive particles CPA2, the flexible circuit board connection pads BP1 or the touch connection pad BP3 is broken and cannot be properly connected, as shown in FIG. 16.

In order to improve the above disadvantages, in the invention, the bonding process between the touch connection pad BP3 on the encapsulation layer ENC and the flexible circuit board connection pad BP1 and the bonding process between the display connection pad BP2 on the substrate SUB and the flexible circuit board connection pads BP1 can be performed in separate stages.

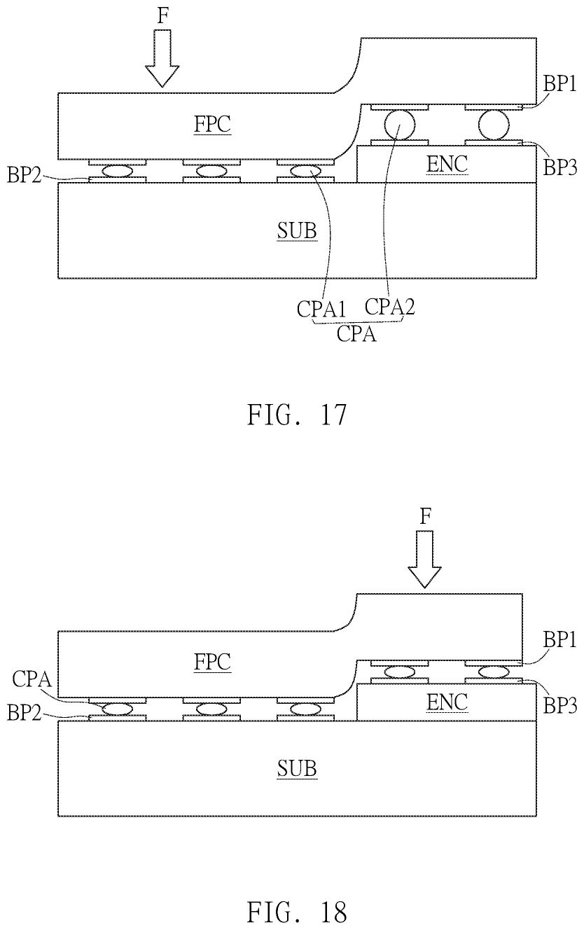

For example, as shown in FIG. 17, a pressing force F can be firstly applied to perform the bonding process between the display connection pad BP2 and the flexible circuit board connection pad BP1; and then, as shown in FIG. 18, the pressure F can be applied to perform the bonding process between the touch connection pad BP3 and the flexible circuit board connection pad BP1. Thereby, the downward pressure F on the substrate SUB and the encapsulation layer ENC can be controlled separately, so that the conductive particles CPA1 on the substrate SUB and the conductive particles CPA2 on the encapsulation layer ENC can have better conduction effects.

In fact, in the invention, the downward pressure F can also be applied to perform the bonding process between the touch connection pad BP3 and the flexible circuit board connection pad BP1, and then the downward pressure F is applied to perform the bonding process between the display connection pad BP2 and the flexible circuit board connection pads BP1.

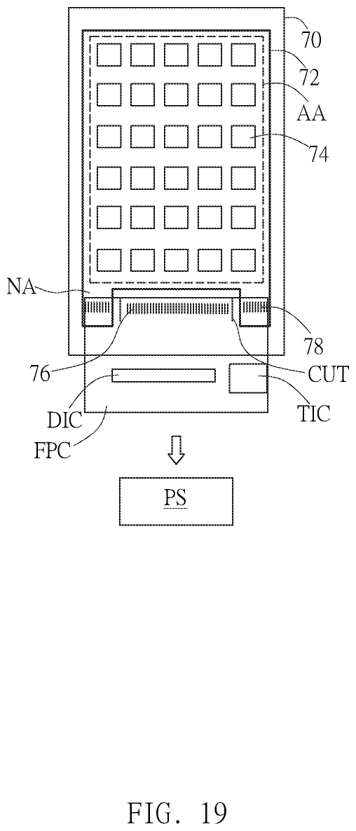

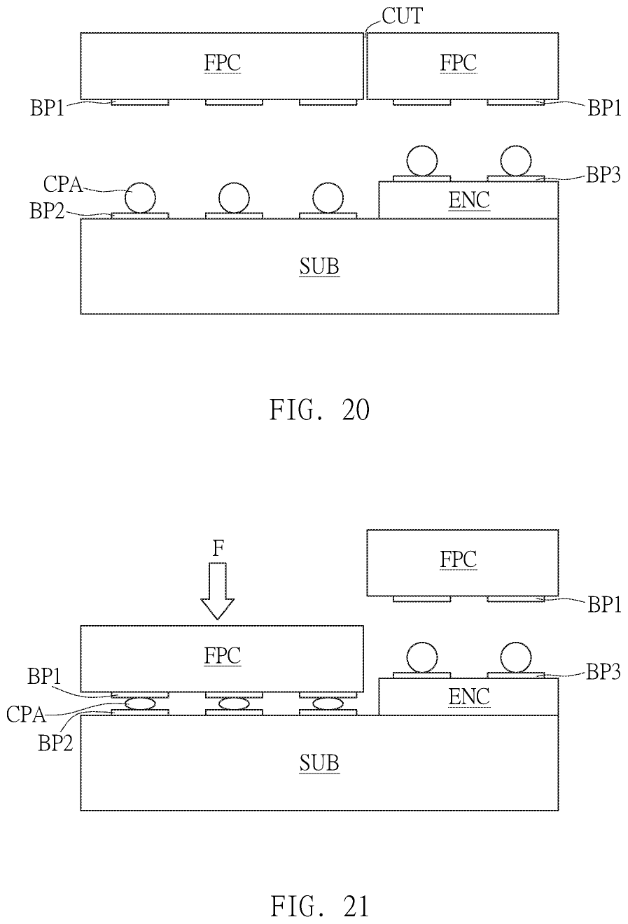

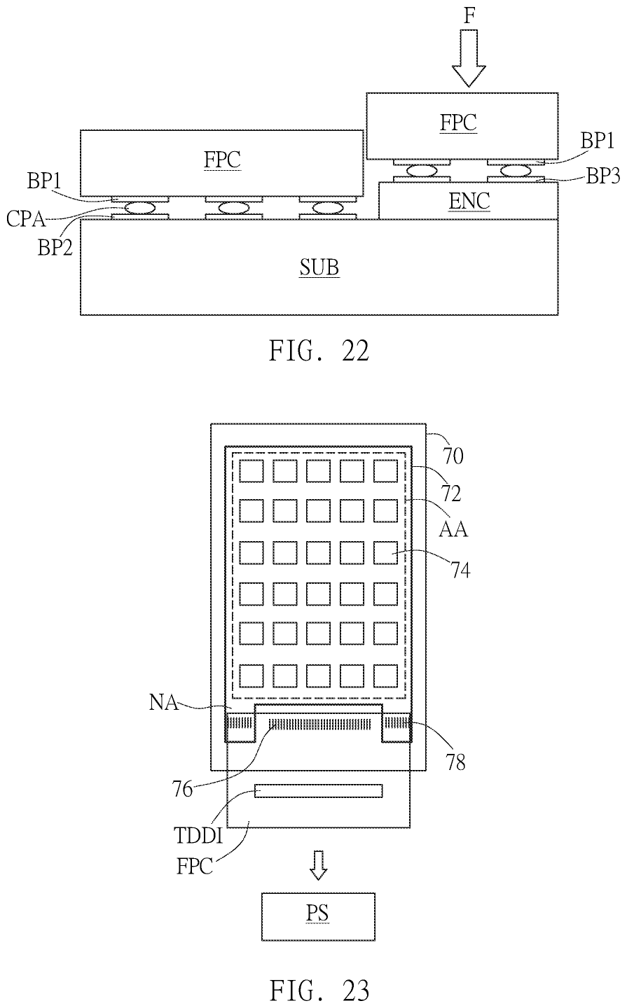

As shown in FIG. 19 to FIG. 22, when the bonding process is performed in separate stages, a region on the flexible circuit board FPC corresponding to the substrate SUB and a region on the flexible circuit board FPC corresponding to the encapsulation layer ENC can be divided from each other to form a separating state CUT. Therefore, when the flexible circuit board FPC is pressed down by the pressing force F, the lateral pressure will not affect the area where the bonding is completed, so that the yield of the process can be further increased.

In another embodiment, as shown in FIG. 23, the above-mentioned driving chip DIC and touch sensing chip TIC can be also integrated into a touch and driving integrated chip TDDI, and the touch and driving integrated chip TDDI can be bonded to the flexible circuit board FPC by the COF encapsulation process. The use of the touch and drive integrated chip TDDI can further reduce the number of times to package the chip and the flexible circuit board FPC to reduce production costs.

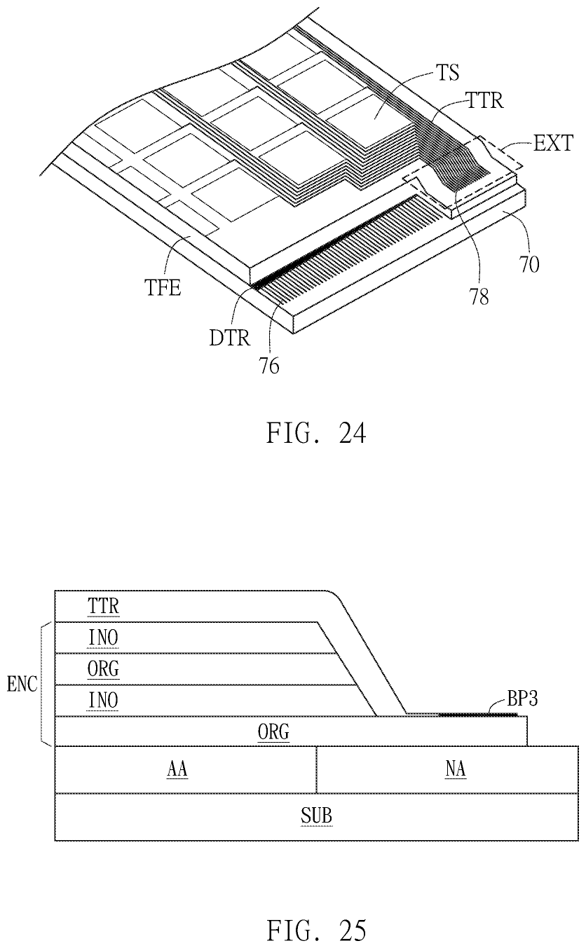

In another embodiment, as shown in FIG. 24, the encapsulation extension area EXT formed in the non-display area of the panel can also form a gradient descent structure in the height direction (Z-axis direction), thereby further reducing the step difference between the touch connection pad 78 on the thin-film encapsulation layer TFE and the substrate 70 and further reduces the complexity of the flexible circuit bonding process.

As shown in FIG. 25, in the gradient descent structure, the extension distances of the inorganic material layer INO and the organic material layer ORG alternately stacked in the encapsulation layer ENC can be different to make the encapsulation layer ENC appears sequentially shrink back to the display area AA from bottom to top. Thereby, the touch electrode traces TTR formed above the encapsulation layer ENC can be connected down through the gradient descent structure to the touch connection pad BP3 disposed on the bottom layer (i.e., the organic material layer ORG) of the encapsulation layer ENC.

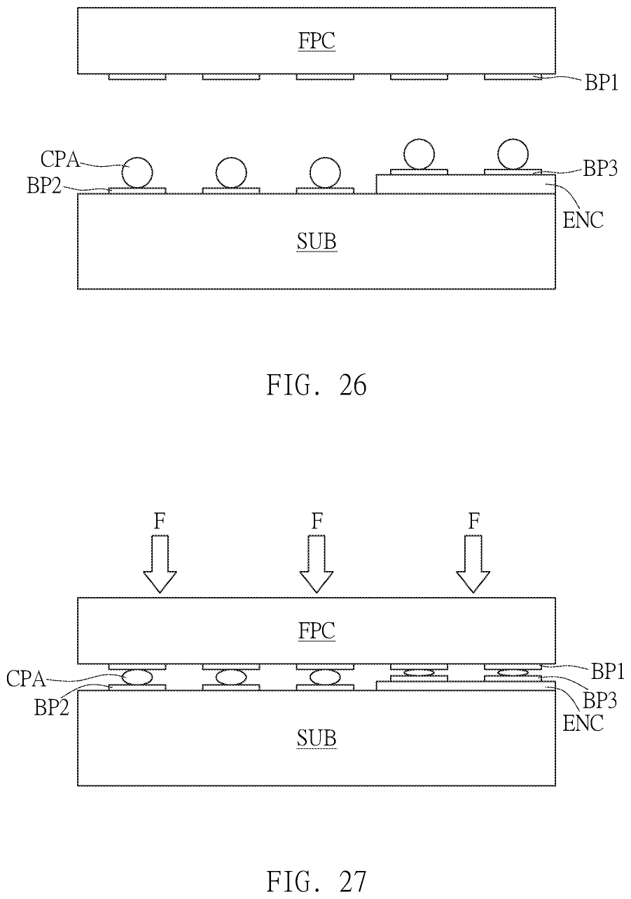

As shown in FIG. 26 and FIG. 27, the step difference between the touch connection pad BP3 on the encapsulation layer ENC and the substrate SUB is significantly smaller than the foregoing embodiment. It should be noted that although the encapsulation layer ENC in FIG. 25 only includes two inorganic material layers INO and two organic material layers ORG stacked alternately, the encapsulation layer ENC can actually include more stacked layers, which is not limited to this. Although the gradient descent structure in FIG. 25 extends to the bottom layer (i.e., the organic material layer ORG) of the encapsulation layer ENC, the gradient descent structure can actually extend to other layers in the encapsulation layer ENC; that is, the touch connection pad BP3 can be disposed in the other layers of the encapsulation layer ENC, which is not limited to this.

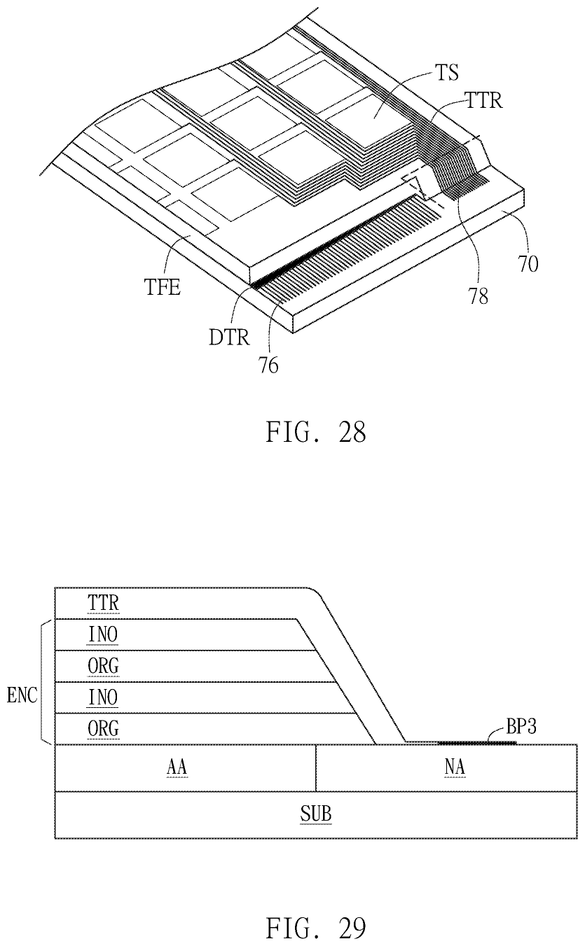

In another embodiment, as shown in FIG. 28, the touch connection pad 78 can be also disposed on the substrate 70, and the gradient descent structure of the thin-film encapsulation layer TFE can be extended to the substrate 70, thereby effectively eliminating the height difference between the touch connection pad 78 and the display connection pad 76.

As shown in FIG. 29, the touch connection pad BP3 can be disposed on the non-display area NA of the panel, and the gradient descent structure of the encapsulation layer ENC can be extended to the non-display area NA of the panel, so that the upper touch electrode trace TTR formed above the encapsulation layer ENC can be connected downward to the touch connection pad BP3 disposed on the non-display area NA of the panel through the gradient descent structure.

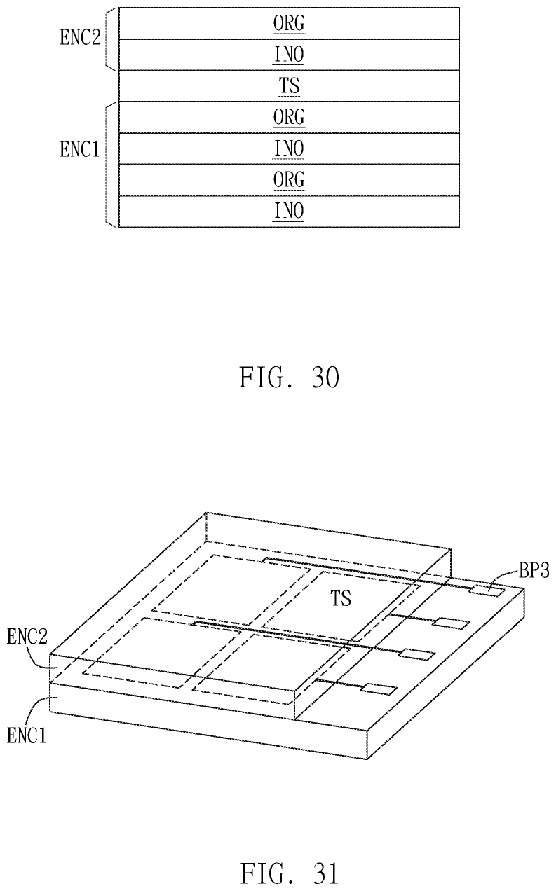

In another embodiment, the touch sensing layer can be integrated into the thin-film encapsulation layer. For example, as shown in FIG. 30, a first partial encapsulation layer ENC1 is formed by overlapping two inorganic material layers INO and two organic material layers ORG with each other, and then the touch sensing layer TS (it may include touch sensing electrodes and their traces) is formed above the first partial encapsulation layer ENC1. Then, a second partial encapsulation layer ENC2 is formed on the touch sensing layer TS by the same thin-film process.

In addition, as shown in FIG. 31, the second partial encapsulation layer ENC2 is formed on the touch sensing layer TS without being formed on the non-display area NA of the panel; that is, there is no encapsulation layer above the touch connection pad BP3 disposed on the non-display area NA of the panel, so that the flexible circuit board FPC can be directly bonded to the upper side of the touch connection pad BP3.

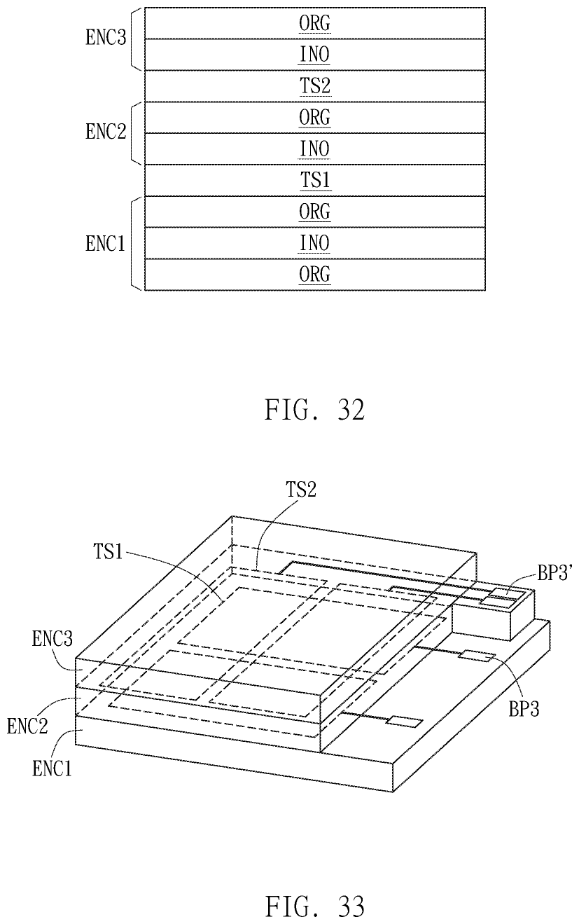

In another embodiment, the touch sensing electrodes and their traces can be formed on different encapsulation layers respectively. For example, as shown in FIG. 32, after the first partial encapsulation layer ENC1 is formed, the first touch sensing layer TS1 (which may include the first touch sensing electrode and its traces), the second partial encapsulation layer ENC2, the second touch sensing layer TS2 (which may include a second touch-sensing electrode and its traces) and the third partial encapsulation layer ENC3 can be sequentially formed. As shown in FIG. 33, the touch connection pad BP3 coupled to the first touch sensing layer TS1 and the touch connection pad BP3′ coupled to the second touch sensing layer TS2 can be respectively disposed above the first partial encapsulation layer ENC1 and the second partial encapsulation layer ENC2, but not limited to this.

It should be noted that after integrating the manufacturing process of the touch sensing layer and the thin-film encapsulation layer, the thin-film encapsulation layer can be used as the insulation layer between the two touch sensing layers, so that the process of manufacturing the insulation layer can be omitted to reduce production time and costs. In addition, when the touch sensing layer is fabricated above the lower encapsulation layer, the step difference between the touch connection pad and the display connection pad can be also reduced, so that the yield of connecting with the flexible circuit board can be improved.

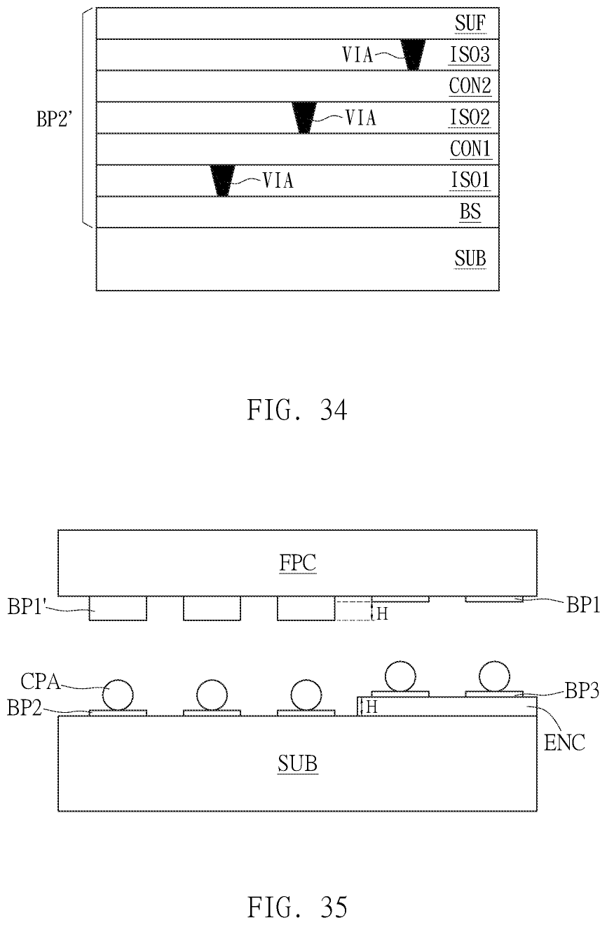

In another embodiment, as shown in FIG. 34, the display connection pad BP2′ disposed on the substrate SUB can be elevated by the OLED diode, thereby the step difference between the display connection pad BP2′ and the touch connection pads BP3 can be reduced. For example, the display connection pad BP2′ can sequentially include a base BS formed of a conductive metal, an insulation layer ISO1, a conductive layer CON1, an insulation layer ISO2, a conductive layer CON2, an insulation layer ISO3 and a surface SUF formed of the conductive metal from bottom to top. And, the vias are formed in the insulation layer ISO1, the insulation layer ISO2 and the insulation layer ISO3 respectively, so that the base BS, the conductive layer CON1, the conductive layer CON2 and the surface SUF can be conducted. Thereby, the height of the display connection pad BP2′ is increased due to the insulation layer ISO1, the insulation layer ISO2 and the insulation layer ISO3, so that the step difference with the encapsulation layer ENC can be reduced.

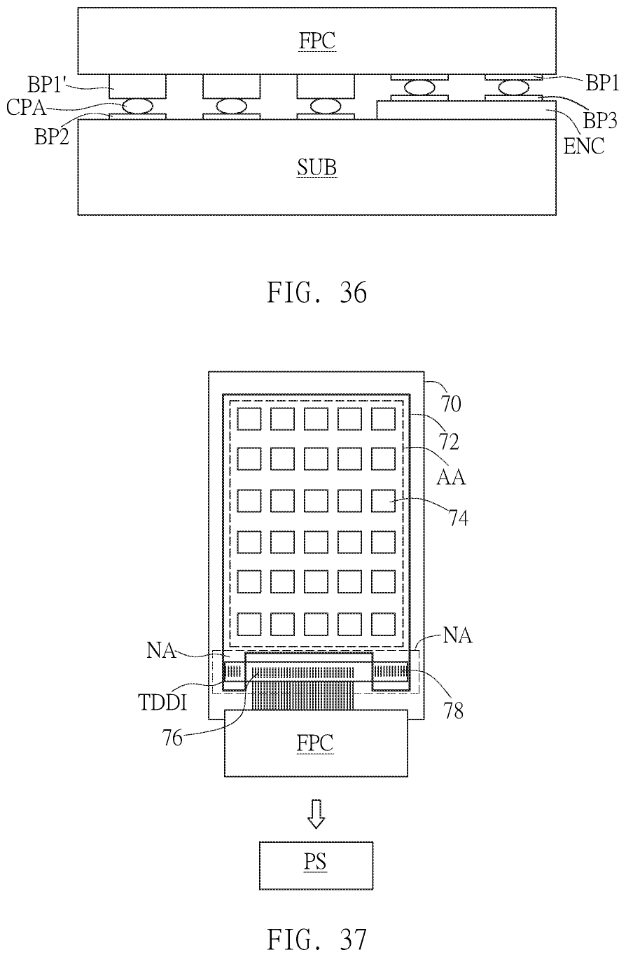

In another embodiment, as shown in FIG. 35 and FIG. 36, the height difference H between the flexible circuit board connection pad BP1′ disposed on the flexible circuit board FPC with respect to the substrate SUB and the flexible circuit board connection pad BP1 with respect to the encapsulation layer ENC can be equal to the height difference H between the display connection pad BP2 disposed on the substrate SUB and the touch connection pad BP3 disposed on the encapsulation layer ENC, and this height difference H is equal to the thickness of the encapsulation layer ENC (for example, Sum), so that the problem of step difference can be effectively solved. In fact, this height difference H can be also different from the thickness of the encapsulation layer ENC. For example, the height of the display connection pad BP2 disposed on the substrate SUB can be reduced by the OLED process, so that the height difference H is reduced and smaller than the thickness of the encapsulation layer ENC, but not limited to this.

In another embodiment, as shown in FIG. 37, the laminated structure of the touch panel in the invention can also be applied to a touch and drive integrated chip TDDI of the chip-on-glass (COG) process. The touch and drive integrated chip TDDI can be directly bonded to the substrate 70 and then connected to the processing system PS via the flexible circuit board FPC.

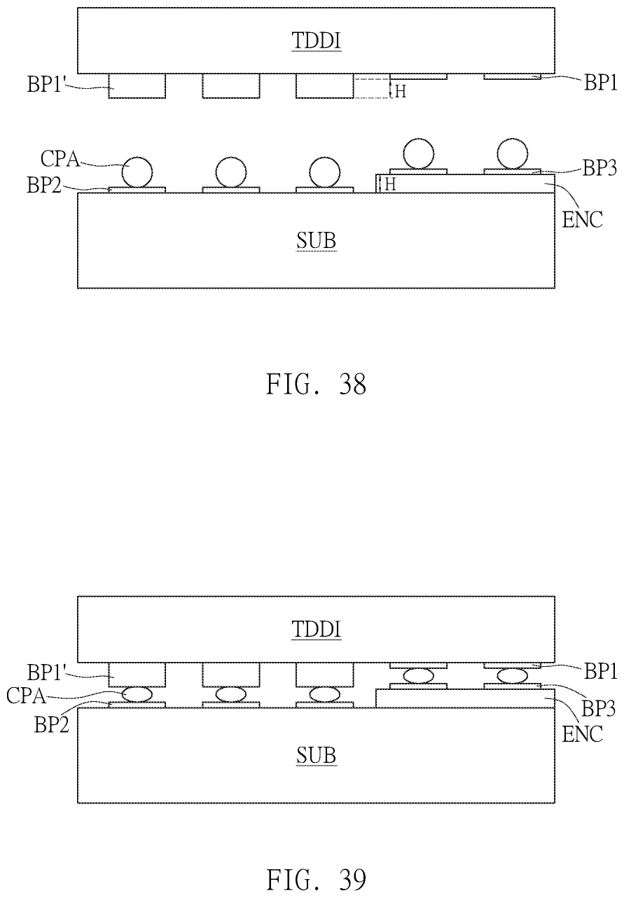

Similarly, as shown in FIG. 38 and FIG. 39, the height difference H between the connection pad BP1′ disposed on the touch and drive integrated wafer TDDI with respect to the substrate SUB and the connection pad BP1 with respect to the encapsulation layer ENC can be equal to the height difference H between the display connection pad BP2 disposed on the substrate SUB and the touch connection pad BP3 disposed on the encapsulation layer ENC, and this height difference H is equal to the thickness of the encapsulation layer ENC (for example, Sum) to effectively improve the problem of step difference. In fact, this height difference H can be also different from the thickness of the encapsulation layer ENC.

Compared to the prior art, the invention provides an innovative laminated structure and a trace layout method of a capacitive touch panel to fabricate the touch sensing electrode on or within a thin-film encapsulation layer of an OLED panel, and the touch sensing chip or a flexible circuit board using a COF package connects the touch connection pads on the encapsulation layer and the display connection pads on the substrate at the same time, so that the traces of the touch sensing electrodes can be directly connected to a flexible circuit board using the COF package or a TDDI, so that the use of flexible circuit boards can be reduced to effectively reduce the manufacturing cost of capacitive touch panel and improve the manufacturing yield.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A capacitive touch panel, comprising:
a plurality of pixels, a laminated structure of each pixel from bottom to top comprising;
a substrate;
a display layer, disposed above the substrate;
a thin-film encapsulation layer, disposed above the display layer with respect to the substrate, the thin-film encapsulation layer comprising alternately stacked organic material layer and inorganic material layer; and
a conductive layer, disposed above the thin-film encapsulation layer or within the thin-film encapsulation layer;
wherein the conductive layer is electrically connected to a connection pad disposed above a non-display area of the display layer.

2. The capacitive touch panel of claim 1, wherein the thin-film encapsulation layer is formed by alternately stacking at least one organic material layer and at least one inorganic material layer using a thin-film encapsulation technology.

3. The capacitive touch panel of claim 1, wherein the display layer comprises a display area and the non-display area.

4. The capacitive touch panel of claim 1, wherein the conductive layer comprises a touch sensing electrode suitable for mutual-capacitance touch sensing technology or self-capacitance touch sensing technology.

5. The capacitive touch panel of claim 4, wherein the conductive layer further comprises a trace coupled to the touch sensing electrode, and the touch sensing electrode is electrically connected to the connection pad through the trace.

6. The capacitive touch panel of claim 1, wherein the display layer comprises an organic light-emitting diode (OLED) multilayer structure.

7. The capacitive touch panel of claim 1, wherein the connection pad is electrically connected to a driving circuit, which is a touch driving circuit disposed on a flexible circuit board or a touch and display driving integrated circuit.

8. The capacitive touch panel of claim 7, wherein the flexible circuit board comprises a first area corresponding to the substrate and a second area corresponding to the thin-film encapsulation layer, and the first area and the second area can be separated from each other to form a separating state.

9. The capacitive touch panel of claim 7, wherein another connection pad is disposed on the flexible circuit board or the touch and display driving integrated circuit, and the connection pad and the another connection pad are electrically connected to each other through conductive particles.

10. The capacitive touch panel of claim 9, wherein still another connection pad is disposed on the substrate, and the still another connection pad and the another connection pad are also electrically connected to each other through the conductive particles.

11. The capacitive touch panel of claim 10, wherein there is a height difference between the connection pad disposed on the thin-film encapsulation layer and the still another connection pad disposed on the substrate.

12. The capacitive touch panel of claim 11, wherein the height difference is equal to a thickness of the thin-film encapsulation layer.

13. The capacitive touch panel of claim 11, wherein a height of the still another connection pad can be reduced by an OLED process, so that the height difference is smaller than a thickness of the thin-film encapsulation layer.

14. The capacitive touch panel of claim 11, wherein a plurality of another connection pads disposed on the flexible circuit board or the touch and display driving integrated circuit comprise a first connection pad corresponding to the substrate and a second connection pad corresponding to the thin-film encapsulation layer; the first connection pad has a first height and the second connection pad has a second height, and a difference between the first height and the second height is equal to the height difference.

15. The capacitive touch panel of claim 1, wherein the thin-film encapsulation layer comprises an encapsulation extension area, and the encapsulation extension area is disposed above the non-display area.

16. The capacitive touch panel of claim 15, wherein the encapsulation extension area forms a gradient descent structure in a height direction, and the conductive layer is electrically connected to the connection pad through the gradient descent structure.

17. The capacitive touch panel of claim 16, wherein the connection pad is disposed on any one organic material layer and any one inorganic material layer of the thin-film encapsulation layer.

18. The capacitive touch panel of claim 16, wherein the connection pad is disposed on the non-display area of the display layer.

19. The capacitive touch panel of claim 1, wherein the thin-film encapsulation layer comprises a first partial encapsulation layer and a second partial encapsulation layer; the conductive layer is formed above the first partial encapsulation layer and the second partial encapsulation layer is formed above the conductive layer; the connection pad electrically connected to the conductive layer is disposed above the first partial encapsulation layer and the second partial encapsulation layer is not formed above the connection pad.

20. The capacitive touch panel of claim 1, further comprising:
another conductive layer, insulated from the conductive layer;
wherein the thin-film encapsulation layer comprises a first partial encapsulation layer, a second partial encapsulation layer and a third partial encapsulation layer; the conductive layer is formed above the first partial encapsulation layer and the second partial encapsulation layer is formed above the conductive layer; the another conductive layer is formed above the second partial encapsulation layer and the third partial encapsulation layer is formed above the another conductive layer; the connection pad electrically connected to the conductive layer is disposed on the first partial encapsulation layer and the connection pad electrically connected to the another conductive layer is disposed on the second partial encapsulation layer; the second partial encapsulation layer and the third partial encapsulation layer are not formed above the connection pad.
